(19) United States
(12) Patent Application Publication
(10) Pub. No.: US 2008/0223611 A1
(43) Pub. Date: Sep. 18, 2008

(54) PRINTED WIRING BOARD AND ELECTRIC APPARATUS

(75) Inventor: Takayuki ASHIDA, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/048,544

(22) Filed: Mar. 14, 2008

(30) Foreign Application Priority Data
Mar. 14, 2007 (JP) 2007-65223

(51) Int. Cl. H05K 1/11

(52) U.S. Cl. 174/262

(57) ABSTRACT

A printed wiring board having a wiring layer formed by a wiring pattern for wiring an electronic circuit comprised of an electric part mounted thereon and including a connecting terminal, a first conductor layer formed by a first conductor pattern that is maintained at either a power potential or a ground potential when the electronic circuit is in operation, a second conductor layer formed by a second conductor pattern that is maintained at either the power potential or the ground potential when the electronic circuit is in operation; and a through hole having the connecting terminal of the electric part inserted therein and including, formed on an internal wall thereof, a conductor film that is directly connected to the first conductor pattern and not directly connected to the second conductor pattern.

### BACKGROUND OF THE INVENTION

1. Field

The present invention relates to a printed wiring board with electric parts mounted thereon and an electric apparatus which includes the printed wiring board and the electric parts mounted on the printed wiring board.

2. Description of the Related Art

A conventional way to construct a desired electronic circuit is to mount electric parts on a printed wiring board, and this method is widely used.

Among such electric parts, there are many parts (IMT: Insert Mounting Technology parts) equipped with lead wires. The lead wires are wire-form connecting terminals (connecting pins) for inputting and outputting signals to and from internal electronic circuits, and for receiving power supplied to the electronic circuit.

A mounting method is employed when mounting an IMT part on a printed wiring board in which through holes are provided in the printed wiring board for inserting lead wires. The lead wires are passed through the through holes, and the portions of the lead wires which protrude from a reverse-side surface are soldered.

Then, a conductor film such as a copper film or the like is formed on the internal walls of the through holes, and the conductor film is connected to wiring extending over the surface of or inside the printed wiring board.

Hence, inserting the lead wires into the through holes and soldering the lead wires in place electrically connects the electronic circuit inside the electric part to the surface or internal-plane wiring of the printed wiring board via the lead wiring, soldering, and conductor film.

Thus, the plurality of electric parts mounted on the printed wiring board is connected by the wiring on the printed wiring board to form an electronic circuit for performing the desired operations.

Here, it is preferable that sufficient solder rise occurs when the lead wires of an electric part are inserted into the through holes provided on the printed wiring board and soldered.

Solder rise is a phenomenon by which melted solder applied to the protruding lead wires on a reverse side of the printed wiring board intrudes into the through holes and rises to a front surface of the printed wiring board.

When the solder rise is insufficient, the amount of solder adhering to the lead wire is insufficient and faults may result.

FIG. 1 is a view of solder rise.

FIG. 1 shows a state in which the lead wire 21 of an electric part 20 has been inserted into a through hole 11 of the printed wiring board 10 and soldered using solder 30.

The printed wiring board 10 includes the through hole 11 which has a conductor film 111 formed on internal walls thereof.

The printed wiring board 10 is a multilayer printed wiring board. In the example shown here, four conductor pattern layers 101,102,103, and 104, which spread across the printed wiring board 10, are connected to the conductor film 111 on the internal wall of the through hole 11.

Here, as an example, the lead wire 21 inserted into the through hole 11 is a lead which connects the ground of the electronic circuit within the electric part 20 to the conductor patterns 101,102,103, and 104. The conductor patterns 101,102,103, and 104 form a ground pattern and spread across the printed wiring board 10.

These conductor patterns 101,102,103, and 104, which form the ground pattern, are all held at the same ground level when the circuit is in operation.

Besides the conductor patterns 101,102,103, and 104, the printed wiring board 10 includes a conductor pattern 131 for use as a power line and a plurality of wiring patterns such as 141,142,143 and 144 for transmitting signals.

Here, as described above, it is desirable that the solder 30 of the soldering melts and rises towards a surface of the printed wiring board 10 when the lead wire 21 is inserted into the through hole 11 and soldering is performed on the reverse side of the printed wiring board 10. In other words, it is desirable that sufficient solder rise occurs.

There is a risk that solder faults will develop under long-term use when the solder rise is insufficient, even if the conductivity between the lead wire 21 and the conductor patterns 101, 102,103, and 104 may be sufficient directly after manufacture.

A thickness of approximately ½ the thickness of the printed wiring board 10 is often used as a lower limit for solder rise. In FIG. 1, the solder rise is approximately ⅓ of the thickness of the printed wiring board, a level which is insufficient.

It may not be possible to obtain sufficient solder rise for the following reasons.

(1) The number of layers of ground and power wiring patterns formed on the surface and internal-planes of the printed wiring board increase as the number of layers in the printed wiring board increases. Thus, the number of layers of wiring patterns to be connected to the internal wall 111 of the through hole 11 also increases. Consequently, the heat generated by soldering is dissipated more easily by the wiring patterns.

The melted solder will begin to harden earlier as a result of the heat dissipation, inhibiting the solder rise.

(2) The thickness of the printed wiring board and thus the height of the through holes increases as the number of layers in the printed wiring board increases. Hence, even with the same amount of solder rise, there will be cases where the reference level of, for instance, ½ of the thickness of the printed circuit board is not reached.

(3) There is a trend towards use of lead-free solder to protect against the damaging effects of lead (element symbol: Pb). Surface treatments are implemented on the printed wiring boards to allow use of the lead-free solder. The surface treatments cause a reduction in the amount of solder rise.

(4) The lead-free solder material itself causes deterioration in the solder rise characteristics.

### SUMMARY

The present invention was conceived in consideration of the above described conditions, and provides a printed wiring board with a structure that allows sufficient solder rise and an electric apparatus using the printed wiring board.

The above-described embodiments of the present invention are intended as examples, and all embodiments of the present invention are not limited to including the features described above.

### BRIEF DESCRIPTION OF THE DRAWINGS

FIG. 1 is a diagram illustrating solder rise;

FIG. 2 shows a portion of a through hole for connecting a connecting terminal of the printed wiring board according to the first embodiment of the present invention;

FIG. 3 is a schematic view of a printed wiring board of a second embodiment of the present invention;

FIG. 4 is a schematic view of a printed wiring board of a third embodiment of the present invention.; and

FIG. 5 is a plan view from a top side of a printed wiring board of a fourth embodiment of the present invention.

### DETAILED DESCRIPTION OF THE PREFERRED EMBODIMENTS

Reference may now be made in detail to embodiments of the present invention, examples of which are illustrated in the accompanying drawings, wherein like reference numerals refer to like elements throughout.

The following describes embodiments of the present invention.

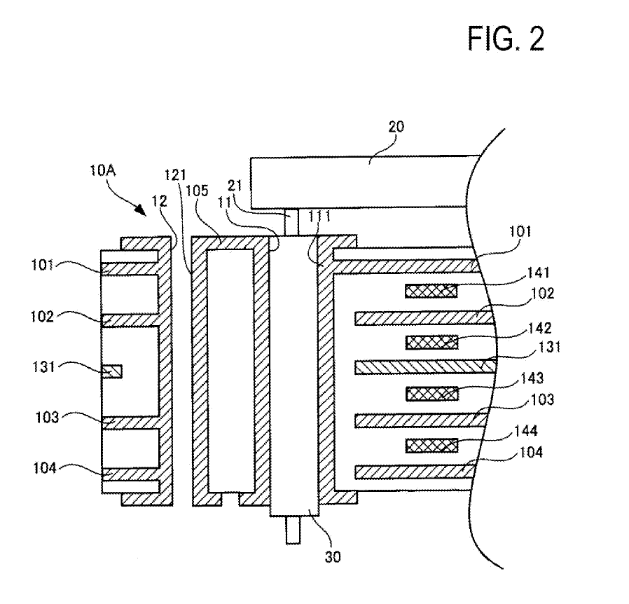

FIG. 2 shows a portion of a through hole (corresponding to a first through hole of the present invention) for joining a connecting terminal of the printed wiring board of the first embodiment of the present invention.

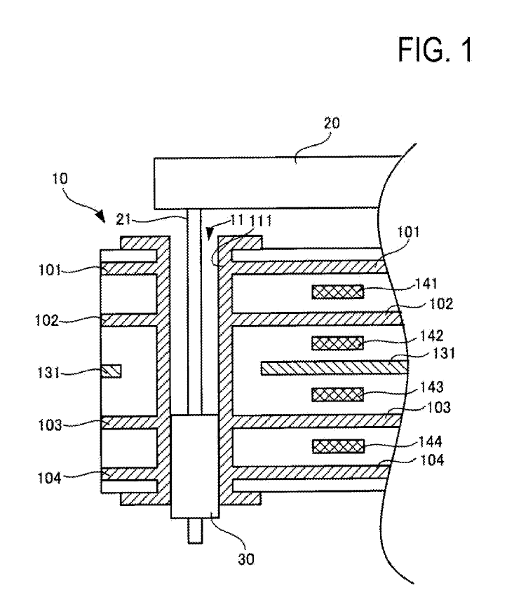

Here, components which are the same as elements in the above-described FIG. 1 are allocated the same symbols, and only the differences between the two printed wiring boards are described below.

In the printed wiring board 10A shown in FIG. 2, the conductor film 111 of an internal wall 18 of the through hole 11 directly connects only to the conductor pattern 101. The conductor pattern 101 is the layer nearest a front surface of the printed wiring board 10A among the conductor patterns 101, 102, 103, and 104. The conductor patterns 101, 102, 103, and 104 are held at ground level when the circuit is in operation.

As a result, the heat is hard to be dissipated when soldering the lead wire 21, and sufficient solder rise can be anticipated.

FIG. 2 shows an example of the solder 30 in a state of having reached the front surface of the printed wiring board as a result of the solder rise.

Note that, of the four layers constituting conductor patterns 101, 102, 103 and 104, the layers constituting the conductor patterns 102, 103, and 104 (i.e. all layers other than the conductor pattern 101 nearest the front surface of the printed wiring board) may connect to the conductor pattern 101 at one or more other locations not shown in the drawings.

In the embodiment shown in FIG. 2, a dummy through hole 12 is formed in the printed wiring board 10A in a position adjacent to the through hole 11. The dummy through hole 12 does not receive a lead wire of an electric part. As in the through hole 11, a conductor film 121 is formed on an internal wall of the dummy through hole 12.

The conductor film 121 on the internal wall of the dummy through hole 12 is connected to the conductor film 111 on the internal wall of the through hole 11 by wiring 105 of the surface layer of the printed wiring board 10A.

Thus, only the conductor pattern 101, which is one layer of the four layers of conductor patterns 101, 102, 103 and 104 and kept to ground level, is directly connected to the conductor film 111 on the internal wall of the through hole 11. However, the conductor patterns 101, 102, 103 and 104 connect to one another via the conductor film 121 of the internal wall of the dummy through hole 12, and are therefore held at the same potential when the circuit is in operation.

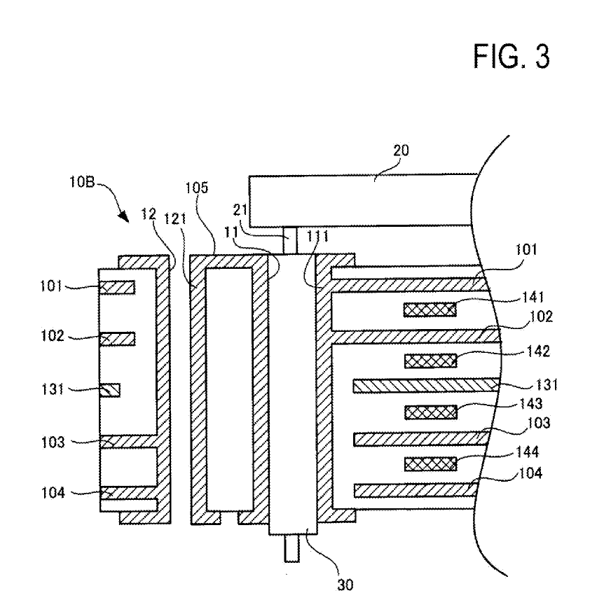

FIG. 3 is a schematic view of the printed wiring board of the second embodiment of the present invention.

The following describes differences between the second embodiment shown in FIG. 3 and the first embodiment shown in FIG. 2.

In the printed wiring board 10B shown in FIG. 3, the conductor film 111 of the internal wall of the through hole 111 is connected directly to the conductor patterns 101 and 102. The conductor patterns 101 and 102 are the two surface-side layers of the four layers constituting the conductor patterns 101,102,103, and 104, which are held at ground level when the circuit is in operation.

A plurality of conductor pattern layers may be connected to the conductor film of the internal wall of the through hole 11 in the above-described manner when sufficient solder rise is desired.

In the printed wiring board 10B shown in FIG. 3, the conductor film 121 of the internal wall of the dummy through hole 12 is connected only to the conductor patterns 103 and 104. The conductor patterns 103 and 104 are the two reverse-side layers that are not directly connected to the conductor film 111 of the through hole 11 of the four layers constituting the conductor patterns 101,102,103, and 104.

In this way, the direct connections of the conductor patterns are shared between the conductor film 111 of the through hole 11 and the conductor film 121 of the dummy through hole 12.

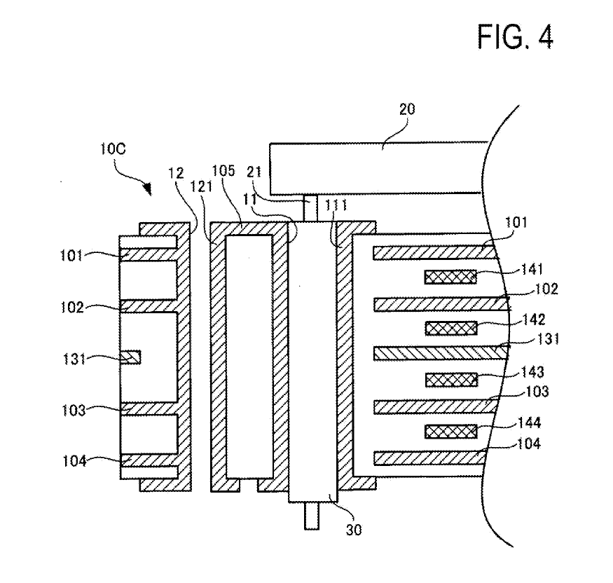

FIG. 4 is a schematic view of the printed wiring board of the third embodiment of the present invention.

The following describes differences between the third embodiment in FIG. 4 and the first and second embodiments shown in FIGS. 2 and 3 respectively.

The conductor film 111 on the internal surface of the through hole 11 of the printed wiring board 10C is not directly connected to any of the four layers constituting the conductor patterns 101,102,103, and 104, which are held at ground level when the circuit is in operation.

Instead, the four layers constituting the conductor patterns 101,102,103 and 104 are all directly connected to the conductor film 121 of the internal wall of the dummy through hole 12 provided in a position adjacent to the through hole 11.

In this manner, the functions can be entirely split between the through hole 11 for inserting and soldering the lead wire 21 of the electric part 12 and the dummy through hole for connecting to the conductor patterns 101,102,103, and 104.

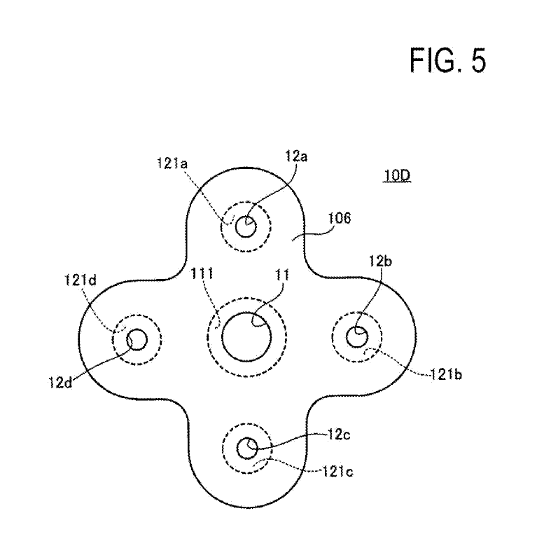

FIG. 5 is a plan view from a top side of the printed wiring board of the fourth embodiment of the present invention.

The following describes differences between the fourth embodiment shown in FIG. 5 and the third embodiment shown in FIG. 4.

FIG. 4 shows only a single dummy through hole 12 adjacent to the through hole 11. FIG. 5, on the other hand, shows a plurality (four here) of dummy through holes 12a, 12b, 12c, and 12d surrounding the through hole 11.

In the same way as in FIG. 4, the conductor film 111 of the internal wall of the through hole 11 in FIG. 5 is not directly connected to any of the four layers constituting the conductor patterns 101,102,103 and 104.

Conductor films 121a, 121b, 121c, and 121d are formed on internal walls of the four corresponding through holes 12a, 12b, 12c, and 12d surrounding the through hole 11 shown in FIG. 5. The conductor film 111 of the through hole 11 is connected to the conductor films 121a, 121b, 121c, and 121d of the four through holes 12a, 12b, 12c, and 12d via wiring pattern 106 on the surface of the printed wiring board 10D.

Further, the conductor films 121a, 121b, 121c, and 121d of the four through holes 12a, 12b, 12c, and 12d each connect to a different layer of the four layers constituting the conductor patterns 101,102,103, and 104.

Thus, a plurality of dummy through holes may be provided and the connections for a multi-layered conductor pattern can be shared among those dummy through holes.

Alternatively, a plurality of dummy through holes may be provided and each of those dummy through holes may be directly connected to all layers of the plurality of conductor patterns.

An arrangement somewhere between the above-described arrangements is also possible. For instance, using the case of FIG. 5 as an example, the dummy though holes 12a and 12b of the four dummy through holes 12a, 12b, 12c, and 12d may be directly connected to the two conductor patterns 101 and 102 while the other two dummy through holes 12c and 12d are directly connected to the other two conductor patterns 103 and 104.

Here, the connection of ground patterns of the first to fourth embodiments have been described, but power patterns can be connected in substantially the same way.

Moreover, it is possible, while taking into account differences between the ground pattern and the power pattern, to apply one of the first to fourth embodiments in one of the power and ground arrangements and apply another of the embodiments in the other of the power and ground arrangements.

Furthermore, although a printed wiring board was described in the embodiments above these embodiments could be seen as embodiments for an electric apparatus including the printed wiring board 10A (or the printed wiring board 10B, or the printed wiring board 10C) and the electric part constructed by soldering a lead wire of the electric part on the printed wiring board.

Although a few preferred embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A printed wiring board having mounted thereon an electric part comprising an electronic circuit and including a connecting terminal, the printed wiring board comprising:
a wiring layer formed by a wiring pattern for wiring the electronic circuit;
a first conductor layer formed by a first conductor pattern that is maintained at either a power potential or a ground potential when the electronic circuit is in operation;
a second conductor layer formed by a second conductor pattern that is maintained at either the power potential or the ground potential when the electronic circuit is in operation; and
a through hole having the connecting terminal of the electric part inserted therein and including a conductor film formed on an internal wall of the through hole, the conductor film directly connected to the first conductor pattern and not directly connected to the second conductor pattern.

2. The printed wiring board according to claim 1, wherein the conductor film is directly connected to a conductor pattern, of the first and second
conductor layers, located on a side of insertion of the connecting terminal and not directly connected to a conductor pattern, of the first and second conductor layers, located on a side opposite to the side of insertion.

3. The printed wiring board of claim 1, further comprising:
a dummy through hole not having the connecting terminal inserted therein and including a conductor film formed on an internal wall of the dummy through hole, the conductor film directly connected to the conductor layer, of the first and second conductor layers, that is not directly connected to the conductor film formed on the internal wall of the through hole.

4. The printed wiring board of claim 1, further comprising:
a first dummy through hole and a second dummy through hole not having the connecting terminal inserted therein, wherein
the first dummy through hole includes a conductor film formed on an internal wall of the first dummy through hole, the conductor film directly connected to the conductor layer, of the first and second conductor layers, that is not directly connected to the conductor film formed on the internal wall of the through hole, and
the second dummy through hole includes a conductor film formed on an internal wall of the second dummy through hole, the conductor film directly connected to the conductor layer, of the first and second conductor layers, that is directly connected to the conductor film formed on the internal wall of the through hole.

5. A printed wiring board having mounted thereon an electric part comprising an electronic circuit and including a connecting terminal, the printed wiring board comprising:
a wiring layer formed by a wiring pattern for wiring the electronic circuit;
a first conductor layer formed by a first conductor pattern that is maintained at either a power potential or a ground potential when the electronic circuit is in operation;
a second conductor layer formed by a second conductor pattern that is maintained at either the power potential or the ground potential when the electronic circuit is in operation;
a through hole having the connecting terminal of the electric part inserted therein and including a conductor film that is not directly connected to the first or second conductor patterns, the conductor film formed on an internal wall of the through hole; and
a dummy through hole not having the connecting terminal inserted therein and including a conductor film that is directly connected to the first and second conductor layers, the conductor film formed on an internal wall of the dummy through hole.

6. A printed wiring board having mounted thereon an electric part comprising an electronic circuit and including a connecting terminal, the printed wiring board comprising:
a wiring layer formed by a wiring pattern for wiring the electronic circuit;
a first conductor layer formed by a first conductor pattern that is maintained at either a power potential or a ground potential when the electronic circuit is in operation;
a second conductor layer formed by a second conductor pattern that is maintained at either the power potential or the ground potential when the electronic circuit is in operation;
a through hole having the connecting terminal of the electric part inserted therein and including a conductor film formed on an internal wall of the through hole, the conductor film not directly connected to the first or second conductor patterns;
dummy through holes not having the connecting terminal inserted therein, wherein a first dummy through hole of the dummy through holes includes a conductor film formed on an internal wall of the first dummy through hole, the conductor film directly connected to the first conductor layer; and
a second dummy through hole of the dummy through holes includes a conductor film formed on an internal wall of the second dummy through hole, the conductor film directly connected to the second conductor layer.

7. An electric apparatus comprising a printed wiring board, the printed wiring board including:
an electric part comprising an electronic circuit and including a connecting terminal;
a wiring layer formed by a wiring pattern for wiring the electronic circuit;
a first conductor layer formed by a first conductor pattern that is maintained at either a power potential or a ground potential when the electronic circuit is in operation;
a second conductor layer formed by a second conductor pattern that is maintained at either the power potential or the ground potential when the electronic circuit is in operation; and
a through hole having the connecting terminal of the electric part inserted and soldered therein and including a conductor film formed on an internal wall of the through hole, the conductor film directly connected to the first conductor pattern and not directly connected to the second conductor pattern.

8. The electric apparatus according to claim 7, wherein
the conductor film is directly connected to a conductor pattern, of the first and second conductor layers, located on a side of insertion of the connecting terminal and not directly connected to a conductor pattern, of the first and second conductor layers, located on a side opposite to the side of insertion.

9. The electric apparatus according to claim 7, further comprising:
a dummy through hole not having the connecting terminal inserted therein and including a conductor film formed on an internal wall of the dummy through hole, the conductor film directly connected to a conductor layer, of the first and second conductor layers, that is not directly connected to the conductor film formed on the internal wall of the through hole.

10. The electric apparatus according to claim 7, further comprising:
dummy through holes not having the connecting terminal inserted therein, wherein a first dummy through hole of the dummy through holes includes a conductor film formed on an internal wall of the first dummy through hole, the conductor film directly connected to a conductor layer, of the first and second conductor layers, that is not directly connected to the conductor film formed on the internal wall of the through hole, and
a second dummy through hole of the dummy through holes includes a conductor film formed on an internal wall of the second dummy through hole, the conductor film directly connected to the conductor layer, of the first and second conductor layers, that is directly connected to the conductor film formed on the internal wall of the through hole.

11. An electric apparatus comprising a printed wiring board, the printed wiring board including:
an electric part comprising an electronic circuit and including a connecting terminal;
a wiring layer formed by a wiring pattern for wiring the electronic circuit;
a first conductor layer formed by a first conductor pattern that is maintained at either a power potential or a ground potential when the electronic circuit is in operation;
a second conductor layer formed by a second conductor pattern that is maintained at either the power potential or the ground potential when the electronic circuit is in operation;
a through hole having the connecting terminal of the electric part inserted and soldered therein and including a conductor film formed on an internal wall of the through hole, the conductor film not directly connected to the first or second conductor patterns; and
a dummy through hole not having the connecting terminal inserted therein and including a conductor film formed on an internal wall of the dummy through hole, the conductor film directly connected to the first and second conductor layers.

12. An electric apparatus comprising a printed wiring board, the printed wiring board including:
an electric part comprising an electronic circuit and including a connecting terminal;
a wiring layer formed by a wiring pattern for wiring the electronic circuit;
a first conductor layer formed by a first conductor pattern that is maintained at either a power potential or a ground potential when the electronic circuit is in operation;
a second conductor layer formed by a second conductor pattern that is maintained at either the power potential or the ground potential when the electronic circuit is in operation;
a through hole having the connecting terminal of the electric part inserted and soldered therein and including a conductor film formed on an internal wall of the through hole, the conductor film not directly connected to the first or second conductor patterns; and
dummy through holes not having the connecting terminal inserted therein, wherein
a first dummy through hole of the dummy through holes includes a conductor film formed on an internal wall of the first dummy through hole, the conductor film directly connected to the first conductor layer conductor layer, and
a second dummy through hole of the dummy through holes includes a conductor film formed on an internal wall of the second dummy through hole, the conductor film directly connected to the second conductor layer.
